(19) United States
(12) Patent Application Publication
(10) Pub. No.: US 2013/0283579 A1
(43) Pub. Date: Oct. 31, 2013

(54) ASSEMBLY DEVICE FOR SEMICONDUCTORS

(71) Applicant: KUO-FONG TSENG, Tu-Cheng (TW)

(72) Inventor: KUO-FONG TSENG, Tu-Cheng (TW)

(73) Assignee: HON HAI PRECISION INDUSTRY CO., LTD., Tu-Cheng (TW)

(21) Appl. No.: 13/615,619

(22) Filed: Sep. 14, 2012

(30) Foreign Application Priority Data
Apr. 25, 2012 (TW) 101114682

(51) Int. Cl. H01L 21/00

(52) U.S. Cl. 29/25.01

(57) ABSTRACT

An exemplary assembly device includes a first loading plate, a movable pole, a driving element, a first camera module, a transparent fetching element, a first processor, a first adjusting element, and a controller. The first loading plate loads a first workpiece. The movable pole is positioned above the first loading plate. The driving element drives the movable pole. The first camera module is positioned on the movable pole, and captures an image of the first workpiece to obtain a first pre-compared image. The fetching element is positioned on the movable pole. The first processor determines whether the first workpiece deviates from a standard position through comparing the first pre-compared image with a first standard image. The first adjusting element adjusts the first workpiece to the standard position. The controller controls the fetching element and the driving element cooperatively to assemble the first workpiece to a second workpiece.

### BACKGROUND

1. Technical Field

The present disclosure relates to assembly devices used in manufacturing and, particularly, to an assembly device for manufacturing semiconductors.

2. Description of Related Art

During a semiconductor manufacturing process, a first workpiece is positioned on a first loading plate, and a second workpiece is positioned on a second loading plate. Then the first loading plate is picked up by an automatic machine, and the first workpiece is directly mounted on the second workpiece to obtain a semiconductor. However, the positions of the first workpiece and the second workpiece prior to operation of the first loading plate may deviate from corresponding predetermined correct positions. Therefore, the quality of the semiconductor obtained may be greatly degraded.

Thus, it is desirable to provide a means that can overcome the above-mentioned limitations.

### BRIEF DESCRIPTION OF THE DRAWINGS

Many aspects of the embodiments should be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic view of an assembly device, according to an exemplary embodiment, wherein the assembly device includes a first processor, a first display, a second processor and a second display.

FIG. 2 is a functional block diagram of the first processor of FIG. 1.

FIG. 3 is a schematic view of an image provided by the first display of FIG. 1.

FIG. 4 is a functional block diagram of the second processor of FIG. 1.

FIG. 5 is a schematic view of an image provided by the second display of FIG. 1.

### DETAILED DESCRIPTION

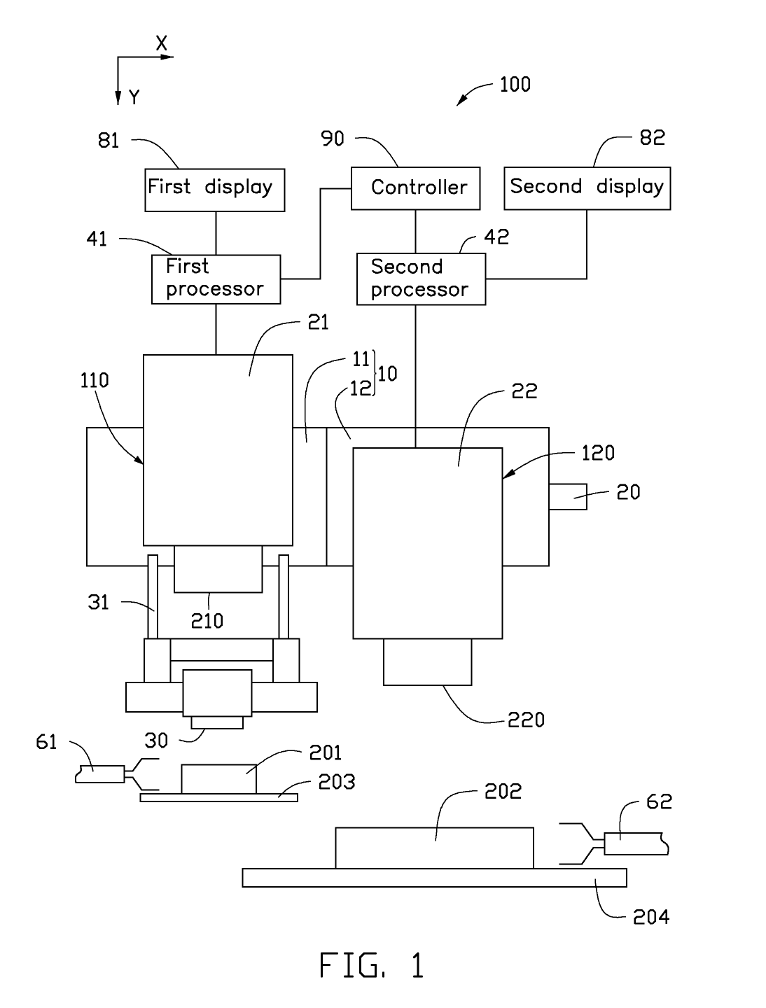

FIG. 1 illustrates an assembly device 100 according to an exemplary embodiment. The assembly device 100 is used for assembling a first workpiece 201 to a second workpiece 202 to obtain a semiconductor. The first workpiece 201 is positioned on a first loading plate 203, and the second workpiece 202 is positioned on a second loading plate 204. In this embodiment, the first workpiece 201 is a wafer, and the second workpiece 202 is a substrate.

The assembly device 100 includes a movable pole 10, a driving element 20, a first camera module 21, a second camera module 22, a fetching element 30, a first processor 41, a second processor 42, a first adjusting element 61, a second adjusting element 62, a first display 81, a second display 82, and a controller 90.

The movable pole 10 is positioned above the first loading plate 203 and the second loading plate 204, and includes a first portion 11 and a second portion 12 fixedly connected to the first portion 11. The first portion 11 defines a first receiving hole 110, and the second portion 12 defines a second receiving hole 120. In other embodiments, the first portion 11 and the second portion 12 are integrally formed as a single monolithic body of material.

The driving element 20 is used for driving the movable pole 10 to move along X-axis directions and Y-axis directions. In FIG. 1, the X-axis directions correspond to a central axis of the movable pole 10, and the Y-axis directions correspond to directions perpendicular to the central axis of the movable pole 10. In this embodiment, the driving element 20 is a motor.

The first camera module 21 is received in the first receiving hole 110, the second camera module 22 is received in the second receiving hole 120, and thus both the first camera module 21 and the second camera module 22 can move along with the movable pole 10. The first camera module 21 and the second camera module 22 are spaced apart from each other a predetermined distance. An optical axis of the first camera module 21 and an optical axis of the second camera module 22 are each substantially perpendicular to an extending direction (i.e., the central axis) of the movable pole 10.

The first camera module 21 has a first light inlet 210 facing the first workpiece 201, and is used for capturing an image of the first workpiece 201 to obtain a first pre-compared image. The first pre-compared image includes a first pre-compared area showing a current position of the first workpiece 201. The second camera module 22 has a second light inlet 220 facing the second workpiece 202, and is used for capturing an image of the second workpiece 202 to obtain a second pre-compared image. The second pre-compared image includes a second pre-compared area showing a current position of the second workpiece 202.

The fetching element 30 is made of transparent material such as transparent plastic, and is positioned on an object side of the first camera module 21. The fetching element 30 is fixed to the first portion 11 of the movable pole 10 through two connecting poles 31, and thus the fetching element 30 can move with the movable pole 10. In this embodiment, the fetching element 30 is a vacuum suction nozzle. In other embodiments, if the driving element 20 cannot drive the movable pole 10 to move along the Y direction, the fetching element 30 or the two connecting poles 31 can be configured to be retractable. In such case, the fetching element 30 can extend to pick up the first workpiece 201, and then draw back.

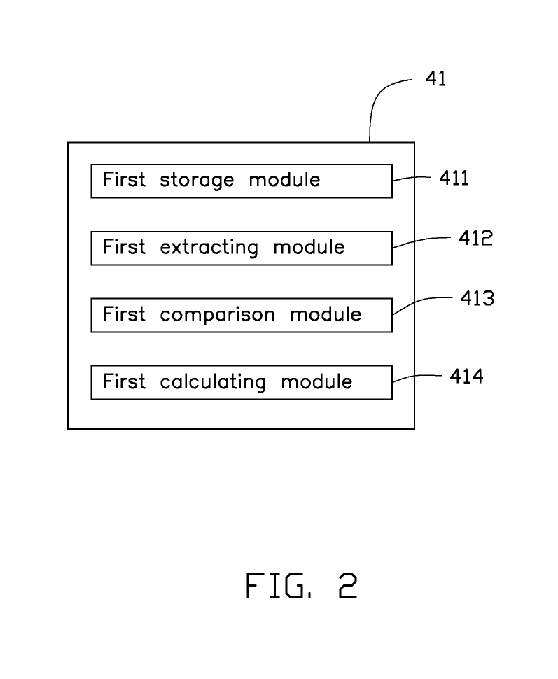

Also referring to FIG. 2, the first processor 41 is electrically connected to the first camera module 21. The first processor 41 is used for determining whether the first workpiece 201 deviates from a standard position. The first processor 41 includes a first storage module 411, a first extracting module 412, a first comparison module 413, and a first calculating module 414.

The first storage module 411 stores a first standard image which includes a first standard area showing the standard position of the first workpiece 201.

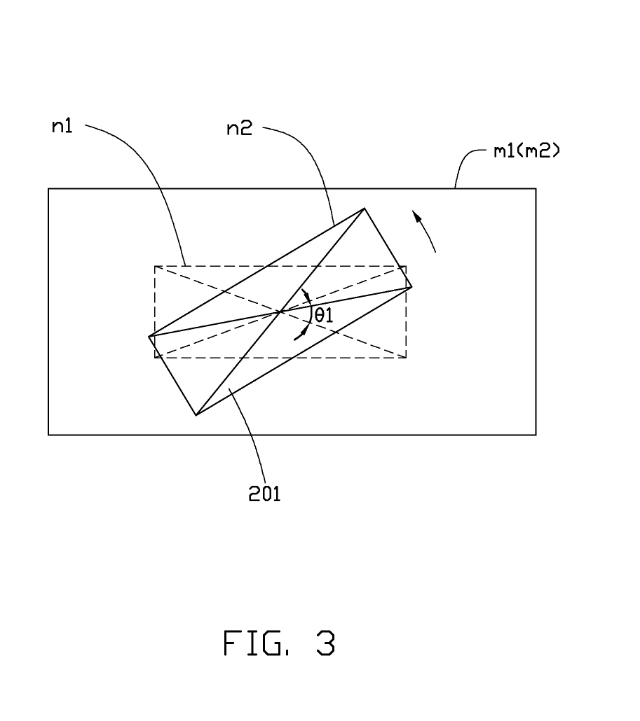

Also referring to FIG. 3, the first extracting module 412 is used for receiving the first standard image and the first pre-compared image, and extracting a frame m1 of the first standard image, an outline n1 of the first standard area, a frame m2 of the first pre-compared image, and an outline n2 of the first pre-compared area.

The first comparison module 413 is used for superposing the frame m2 of the first pre-compared image and the frame m1 of the first standard image, and then determining whether the outline n2 of the first pre-compared area is superposed with the outline n1 of the first standard area in order to determine whether the first workpiece 201 deviates from the standard position. If the outline n2 of the first pre-compared area is superposed with the outline n1 of the first standard area, the first comparison module 413 determines that the current position of the first workpiece 201 does not deviate from the standard position of the first workpiece 201. If the outline n2 of the first pre-compared area is not superposed with the outline n1 of the first standard area, the first comparison module 413 determines that the current position of the first workpiece 201 deviates from the standard position of the first workpiece 201, and the first calculating module 414 is used for calculating a first offset direction (shown as a curved arrow in FIG. 3) and a first deviation angle θ1 of the first workpiece 201.

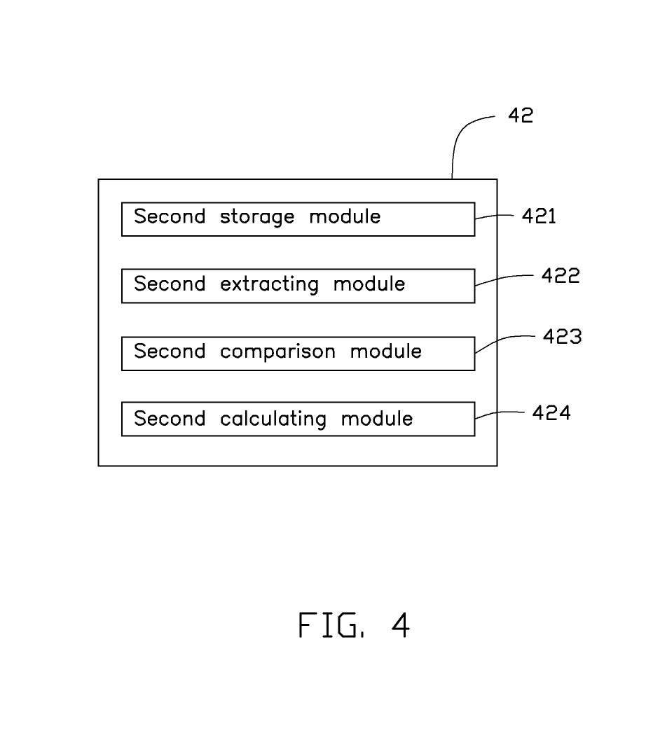

Also referring to FIG. 4, the second processor 42 is electrically connected to the second camera module 22, and is used for determining whether the current position of the second workpiece 202 deviates from a standard position of the second workpiece 202. The second processor 42 includes a second storage module 421, a second extracting module 422, a second comparison module 423, and a second calculating module 424.

The second storage module 421 stores a second standard image which includes a second standard area showing the standard position of the second workpiece 202.

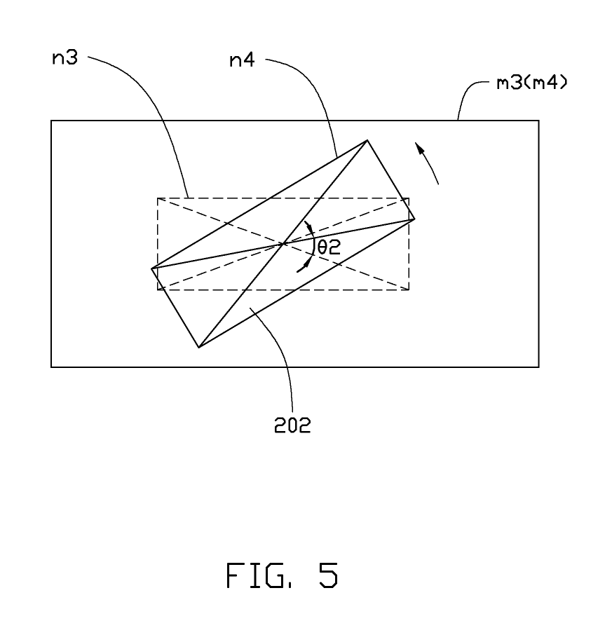

Also referring to FIG. 5, the second extracting module 422 is used for receiving the second standard image and the second pre-compared image, and extracting a frame m3 of the second standard image, an outline n3 of the second standard area, a frame m4 of the second pre-compared image, and an outline n4 of the second pre-compared area.

The second comparison module 423 is used for superposing the frame m4 of the second pre-compared image and the frame m3 of the second standard image, and then determining whether the outline n4 of the second pre-compared area is superposed with the outline n3 of the second standard area in order to determine whether the current position of the second workpiece 202 deviates from the standard position of the second workpiece 202. If the outline of the second pre-compared area is superposed with the outline n3 of the second standard area, the second comparison module 423 determines that the current position of the second workpiece 202 does not deviate from the standard position of the second workpiece 202. If the outline n4 of the second pre-compared area is not superposed with the outline n3 of the second standard area, the second comparison module 423 determines that the current position of the second workpiece 202 deviates from the standard position of the second workpiece 202, and the second calculating module 424 is used for calculating a second offset direction (shown as a curved arrow in FIG. 5) and a second deviation angle θ2 of the second workpiece 202.

The first adjusting element 61 is electrically connected to the first processor 41, and is used for adjusting the current position of the first workpiece 201 according to the first offset direction and the first deviation angle θ1. The second adjusting element 62 is electrically connected to the second processor 42, and is used for adjusting the current position of the second workpiece 202 according to the second offset direction and the second deviation angle θ2. In this embodiment, the first adjusting element 61 and the second adjusting element 62 are manipulators for rotating the first workpiece 201 and the second workpiece 202, respectively. In other embodiments, the first adjusting element 61 and the second adjusting element 62 can be rotary motors for rotating the first loading plate 203 and the second loading plate 204, respectively.

The first camera module 21 is further used for capturing the adjusted first workpiece 201 to obtain a third pre-compared image. The third pre-compared image includes a third pre-compared area showing the adjusted current position of the first workpiece 201. The first extracting module 412 is further used for receiving the third pre-compared image, and extracting a frame of the third pre-compared image and an outline of the third pre-compared area. The first comparison module 413 is further used for superposing the frame of the third pre-compared image and the frame m1 of the first standard image, and then determining whether the outline of the third pre-compared area is superposed with the outline n1 of the first standard area in order to determine whether the first workpiece 201 has been adjusted to the standard position.

If the outline of the third pre-compared area is superposed with the outline n1 of the first standard area, then the first comparison module 413 determines that the first workpiece 201 has been adjusted to the standard position. If the outline of the third pre-compared area is not superposed with the outline n1 of the first standard area, then the first comparison module 413 determines that the first workpiece 201 has not been adjusted to the standard position, and the first calculating module 414 further calculates a third offset direction and a third deviation angle (not illustrated) of the first workpiece 201. The first adjusting element 61 adjusts the first workpiece 201 again according to the third offset direction and the third deviation angle.

The second camera module 22 is further used for capturing the adjusted second workpiece 202 to obtain a fourth pre-compared image. The fourth pre-compared image includes a fourth pre-compared area showing the adjusted current position of the second workpiece 202. The second extracting module 422 is further used for receiving the fourth pre-compared image, and extracting a frame of the fourth pre-compared image and an outline of the fourth pre-compared area. The second comparison module 423 is further used for superposing the frame of the fourth pre-compared image and the frame m3 of the second standard image, and then determining whether the outline of the fourth pre-compared area is superposed with the outline n3 of the second standard area in order to determine whether the second workpiece 202 has been adjusted to the standard position.

If the outline of the fourth pre-compared area is superposed with the outline n3 of the second standard area, the second comparison module 423 determines that the second adjusted workpiece 202 has been adjusted to the standard position. If the outline of the fourth pre-compared area is not superposed with the outline n3 of the second standard area, the second comparison module 423 determines that the second workpiece 202 has not been adjusted to the standard position, and the second calculating module 62 calculates a fourth offset direction and a fourth deviation angle (not illustrated) of the second workpiece 202. The second adjusting element 62 adjusts the second workpiece 202 again according to the fourth offset direction and the fourth deviation angle.

Referring to FIG. 3, the first display 81 is used for displaying the frame m1 of the first standard image, the frame m2 of the first pre-compared image, the outline n1 of the first standard area, and the outline n2 of the first pre-compared area at the same time. The frame m1 of the first standard image is shown as a continuous line, the outline n1 of the first standard area is shown as a broken line, and both the frame m2 of the first pre-compared image and the outline n2 of the first pre-compared image are shown as continuous lines. The first display 81 is further used for displaying the first offset direction and the first deviation angle θ1.

After the first adjusting element 61 adjusts the first workpiece 201, the first display 81 is used for displaying the frame m1 of the first standard image, the frame of the third pre-compared image, the outline n1 of the first standard area, and the outline of the third pre-compared area at the same time. The first display 81 is further used for displaying the third offset direction and the third deviation angle.

Referring to FIG. 5, the second display 82 is used for displaying the frame m3 of the second standard image, the outline n3 of the second standard area, the frame m4 of the second pre-compared image, and the outline n4 of the second pre-compared area. The frame m3 of the second standard image is shown as a continuous line, the outline n3 of the second standard area is shown as a broken line, and both the frame m4 of the second pre-compared image and the outline n4 of the second pre-compared image are shown as continuous lines. The second display 82 is further used for displaying the second offset direction and the second deviation angle θ2.

After the second adjusting element 62 adjusts the second workpiece 202, the second display 82 is used for displaying the frame m3 of the second standard image, the outline n3 of the second standard area, the frame of the fourth pre-compared image, and the outline of the fourth pre-compared area at the same time. The second display 82 is further used for displaying the fourth offset direction and the fourth deviation angle.

In this embodiment, the first display 81 and the second display 82 are liquid crystal displays (LCDs).

The controller 90 is electrically connected to the first comparison module 413 and the second comparison module 423, and is used for controlling the fetching element 30 to fetch the first workpiece 201, and controlling the driving element 20 to drive the movable pole 10 to mount the first workpiece 201 on the second workpiece 202 when the first workpiece 201 and the second workpiece 202 have been adjusted to the corresponding standard positions.

By employing the assembly device 100, the first workpiece 201 and the second workpiece 202 can be accurately adjusted to the corresponding standard positions, whereupon the controller 90 controls the driving element 20 to mount the first workpiece 201 to the second workpiece 202. Therefore, the quality of the semiconductor thus formed can be greatly improved.

It will be understood that the above particular embodiments are shown and described by way of illustration only. The principles and the features disclosed may be employed in various and numerous embodiments thereof without departing from the scope of the disclosure. The above-described embodiments illustrate the scope of the disclosure but do not restrict the scope of the disclosure.

What is claimed is:

1. An assembly device for assembling a first workpiece to a second workpiece to obtain a semiconductor, the assembly device comprising:
a first loading plate for loading the first workpiece;
a movable pole positioned above the first loading plate;
a driving element configured for driving the movable pole;
a first camera module positioned on the movable pole, and configured for capturing an image of the first workpiece to obtain a first pre-compared image;
a fetching element made of transparent material, and configured for picking up the first workpiece, wherein the fetching element is positioned on the movable pole, and is on the object side of the first camera module;
a first processor configured for determining whether the first workpiece deviates from a standard position of the first workpiece according to a comparison made between the first pre-compared image and a first standard image of the first workpiece;
a first adjusting element configured for adjusting the first workpiece to a standard position if the first workpiece deviates from the standard position; and
a controller configured for controlling the fetching element to pick up the first workpiece, and controlling the driving element to drive the movable pole to assemble the first workpiece to the second workpiece.

2. The assembly device of claim 1, wherein an optical axis of the first camera module is substantially perpendicular to a central axis of the movable pole.

3. The assembly device of claim 1, wherein the first pre-compared image has a first pre-compared area showing the current position of the first workpiece, the first processor comprises a first storage module, a first extracting module, and a first comparison module, the first storage module stores the first standard image, and the first standard image has a first standard area showing the standard position of the first workpiece; the first extracting module is configured for extracting the frame of the first pre-compared image, the outline of the first pre-compared area, the frame of the first standard image, and the outline of the first standard area; the first comparison module is configured for superposing the frame of the first pre-compared image and the frame of the first standard image, and then determining whether the outline of the first pre-compared area is superposed with the outline of the first standard area to determine whether the first workpiece deviates from the standard position.

4. The assembly device of claim 3, wherein if the outline of the first pre-compared area is superposed with the outline of the first standard area, the comparison module determines that the first workpiece does not deviate from the standard position; and if the outline of the first pre-compared area is not superposed with the outline of the first standard area, the comparison module determines that the first workpiece deviates from the standard position.

5. The assembly device of claim 4, further comprising a first display, wherein the first display is configured for displaying the frame of the first standard image, the outline of the first standard area, the frame of the first pre-compared image, and the outline of the first pre-compared area at the same time.

6. The assembly device of claim 5, wherein the first processor further comprises a first calculating module for calculating a first offset direction and a first deviation angle of the first workpiece if the first workpiece deviates from the standard position.

7. The assembly device of claim 6, wherein the first display is further configured for displaying the first offset direction and the first deviation angle.

8. The assembly device of claim 5, further comprising a second loading plate, a second camera module, a second processor, and a second adjusting element; wherein the second camera module is positioned on the movable pole, and is spaced a predetermined distance from the first camera module; the second loading plate is configured for loading the second workpiece; the second camera module is configured for capturing an image of the second workpiece to obtain a second pre-compared image; the second processor is configured for determining whether the second workpiece deviates from a standard position of the second workpiece according to a comparison made between the second pre-compared image and a second standard image of the second workpiece; and the second adjusting element is configured for adjusting the second workpiece to the standard position if the second workpiece deviates from the standard position.

9. The assembly device of claim 8, wherein an optical axis of the second camera module is substantially perpendicular to a central axis of the movable pole.

10. The assembly device of claim 8, wherein the second pre-compared image has a second pre-compared area showing the current position of the second workpiece, the second processor comprises a second storage module, a second extracting module, and a second comparison module, the second storage module stores the second standard image, and the second standard image has a second standard area showing the standard position of the second workpiece; the second extracting module is configured for extracting the frame of the second pre-compared image, the outline of the second pre-compared area, the frame of the second standard image, and the outline of the second standard area; and the second comparison module is configured for superposing the frame of the second pre-compared image and the frame of the second standard image, and then determining whether the outline of the second pre-compared area is superposed with the outline of the second standard area to determine whether the second workpiece deviates from the standard position.

11. The assembly device of claim 10, wherein if the outline of the second pre-compared area is superposed with the outline of the second standard area, the second comparison module determines that the second workpiece does not deviate from the standard position; and if the outline of the second pre-compared area is not superposed with the outline of the second standard area, the second comparison module determines that the second workpiece deviates from the standard position.

12. The assembly device of claim 11, further comprising a second display; wherein the second display is configured for displaying the frame of the second standard image, the outline of the second standard area, the frame of the second pre-compared image, and the outline of the second pre-compared area at the same time.

13. The assembly device of claim 12, wherein the second processor further comprises a second calculating module for calculating a second offset direction and a second deviation angle of the second workpiece if the second workpiece deviates from the standard position.

14. The assembly device of claim 13, wherein the second display is further configured for displaying the second offset direction and the second deviation angle.

15. The assembly device of claim 13, wherein the first camera module is further configured for capturing the adjusted first workpiece to obtain a third pre-compared image, and the third pre-compared image has a third pre-compared area showing the adjusted current position of the adjusted first workpiece; the first extracting module is further configured for receiving the third pre-compared image, and extracting the frame of the third pre-compared image and the outline of the third pre-compared area; and the first comparison module is further configured for superposing the frame of the third pre-compared image and the frame of the first standard image, and then determining whether the outline of the third pre-compared area is superposed with the outline of the first standard area to determine whether the adjusted first workpiece had been adjusted to the standard position.

16. The assembly device of claim 15, wherein the first display is further configured for displaying the frame of the first standard image, the outline of the first standard area, the frame of the third pre-compared image, and the outline of the third pre-compared area at the same time.

17. The assembly device of claim 16, wherein the first calculating module is further configured for calculating a third offset direction and a third deviation angle of the adjusted first workpiece if the adjusted first workpiece deviates from the standard position, and the first display is further configured for displaying the third offset direction and the third deviation angle.

18. The assembly device of claim 17, wherein the second camera module is further configured for capturing the adjusted second workpiece to obtain a fourth pre-compared image, and the fourth pre-compared image has a fourth pre-compared area showing the adjusted current position of the adjusted second workpiece; the second extracting module is further configured for receiving the fourth pre-compared image, and extracting the frame of the fourth pre-compared image and the outline of the fourth pre-compared area; and the second comparison module is further configured for superposing the frame of the fourth pre-compared image and the frame of the second standard image, and then determining whether the outline of the fourth pre-compared area is superposed with the outline of the second standard area to determine whether the adjusted second workpiece had been adjusted to the standard position.

19. The assembly device of claim 18, wherein the second display is further configured for displaying the frame of the second standard image, the outline of the second standard area, the frame of the fourth pre-compared image, and the outline of the fourth pre-compared area at the same time.

20. The assembly device of claim 19, wherein the second calculating module is further configured for calculating a fourth offset direction and a fourth deviation angle of the adjusted second workpiece if the adjusted second workpiece deviates from the standard position, and the second display is further configured for displaying the fourth offset direction and the fourth deviation angle.
